(19) United States
(12) Patent Application Publication
(10) Pub. No.: US 2005/0099778 A1
(43) Pub. Date: May 12, 2005

(54) Circuit assembly and method for producing the same

(75) Inventor: Ryuji Nakanishi, Yokkaichi-city (JP)

Correspondence Address: OLIFF & BERRIDGE, PLC, P.O. BOX 19928, ALEXANDRIA, VA, 22320, US

(73) Assignee: SUMITOMO WIRING SYSTEMS, LTD., Yokkaichi-city (JP)

(21) Appl. No.: 10/922,989

(22) Filed: Aug. 23, 2004

(30) Foreign Application Priority Data
Nov. 11, 2003 (JP) 2003-381400

(51) Int. Cl. H01R 12/00; H05K 7/20

(52) U.S. Cl. 361/704; 439/76.2

(57) ABSTRACT

An insulation adhesive is applied to an bonding surface of a heat radiation member to positively ensure a thickness of an insulation layer when bonding a circuit section and a heat radiation member through the insulation layer. An insulation sheet-like element provided with numerous flow paths is superposed on the insulation adhesive to seep the insulation adhesive through the flow paths before the insulation adhesive is solidified. A circuit section is stacked further on the insulation sheet-like element. The insulation adhesive bonds the circuit section and heat radiation member to each other.

### CLAIM FOR PRIORITY

The present invention claims priority to Japanese Patent Application JP 2003-381400 filed on Nov. 11, 2003. The entire disclosure of the prior application is hereby incorporated by reference herein in its entirety.

### BACKGROUND OF THE INVENTION

1. Field of Invention

This invention relates to a circuit assembly including a circuit section constituting an electrical power circuit, a heat radiation member, and an insulation layer interposed between the circuit section and the heat radiation member, and relates to a method for producing the circuit assembly.

2. Description of Related Art

Heretofore, an electrical junction box, in which a plurality of bus bars constitute a distribution circuit and a switching device is installed, has been generally known as means for distributing an electrical power from a common electrical source on a vehicle to respective electronic units. Furthermore, means for downsizing the electrical junction box have been developed recently. For example, Japanese Patent Public Publication No. 2003-164039 discloses a method for producing a circuit assembly corresponding to a downsized electrical junction box. The method for producing the circuit assembly includes the steps of: forming a distribution circuit by a plurality of bus bars; providing a semiconductor switching-device in an electrical power circuit; bonding the bus bars and a control circuit substrate for controlling actuation of the semiconductor switching-device to each other to form a circuit section; mounting a casing on the circuit section at the side of the control circuit substrate; and adhering a heat radiation member to the circuit section at the bus bar side.

In order to positively insulate the circuit section from the heat radiation member when bonding them, an insulation adhesive is applied to a bonding surface of the heat radiation member, and is dried to form an insulation layer. Then, an insulation adhesive is applied to the insulation layer or the circuit section at the bus bar side to bond the circuit section and heat radiation member to each other. Thus, after forming the insulation layer with a given thickness by solidifying the initially applied insulation adhesive, an insulation adhesive is further applied to the insulation layer to bond the circuit section on the heat radiation member. Consequently, it is possible to ensure a minimum thickness of the insulation layer by the initial insulation layer, even if a force for pressing the circuit section is slightly over a given value upon bonding.

### SUMMARY OF THE INVENTION

However, although such a method of bonding the circuit section on the heat radiation member can ensure a thickness of the insulation layer between the circuit section and the heat radiation member, the adhesive applying step must be carried out twice and the respective steps require a time for solidifying the adhesive. This will lower efficiency in working and increase a cost in production.

In view of the above problems, an object of exemplary embodiments of the invention is to provide a circuit assembly in which an insulation layer is easily formed between a circuit section and a heat radiation member and a thickness of the insulation layer can be ensured by a simple structure and to provide a method for producing the circuit assembly.

An exemplary embodiment of the invention is directed to a method for producing a circuit assembly by adhering a circuit section constituting an electrical power circuit to a bonding surface of a heat radiation member. The method includes the steps of: applying an insulation adhesive to the bonding surface of the heat radiation member; superposing an insulation sheet-like element on the insulation adhesive before the insulation adhesive is solidified, the insulation sheet-like element having numerous flow paths through which the insulation adhesive can pass in a thickness direction of the element; and superposing the circuit section on the insulation sheet-like element and pressing the circuit section toward the bonding surface. Consequently, the circuit section and heat radiation member are bonded to each other by the insulation adhesive seeping through the insulation sheet-like element.

An exemplary embodiment of the invention specified in Claim 2 is directed to an insulation sheet-like element having numerous flow paths is selected from a sheet-like material made by braiding insulation fibers in the element-superposing step.

An exemplary embodiment of the invention is directed to the circuit assembly including a circuit section constituting an electrical power circuit and a heat radiation member having a bonding surface to which the circuit section is adhered. The circuit assembly includes an insulation sheet-like element has numerous flow paths through which the insulation adhesive can pass in a thickness direction of the element; the insulation sheet-like element is interposed between the bonding surface of the heat radiation member and the circuit section; and the circuit section is adhered to the bonding surface.

An exemplary embodiment of the invention is directed to the insulation sheet-like element having numerous flow paths is selected from a sheet-like material made by braiding insulation fibers.

### BRIEF DESCRIPTION OF THE DRAWINGS

The accompanying drawings, which are incorporated into and constitute a part of the specification, illustrate one or more embodiments of the invention and, taken with the detailed description, serve to explain the principles and implementations of the invention. In the drawings:

FIG. 1 is an exploded perspective view of a circuit assembly produced by a method in accordance with the invention.

FIG. 2 is a perspective view of a heat radiation member in accordance with the invention, illustrating the heat radiation member applied with an insulation adhesive.

FIG. 3 is a perspective view of the heat radiation member shown in FIG. 2, illustrating an insulation sheet-like element being stacked onto the insulation adhesive on the heat radiation member.

### DETAILED DESCRIPTION OF PREFERRED EMBODIMENTS

Referring now to the drawings, an exemplary embodiment of a circuit assembly in accordance with the invention will be described below. The insulation adhesive is applied to the bonding surface of the heat radiation member. The insulation sheet-like element has the numerous flow paths through which the insulation adhesive can pass in a thickness direction of the element. The insulation sheet-like element is superposed on the insulation adhesive before the insulation adhesive is solidified. The circuit section is superposed on the insulation sheet-like element. The circuit section is pressed toward the bonding surface, thereby bonding the circuit section and heat radiation member by the insulation adhesive.

Accordingly, even if a layer of the insulation adhesive is collapsed by a relatively great pressure onto the circuit section, a minimum thickness of the adhesive layer can be ensured through the insulation sheet-like element interposed between the circuit section and the bonding surface by a work of applying the adhesive to the bonding surface only at one time. Also, because the numerous flow paths that can pass the adhesive are formed in the insulation sheet-like element, the insulation adhesive can be uniformly applied to the bonding surface of the circuit section stacked on the insulation sheet-like element and the bonding between the circuit section and the heat radiation member can be positively obtained through the insulation sheet-like element.

Further, the insulation sheet-like element is selected from a sheet-like material made by braiding the insulation fibers, so that the numerous flow paths that can pass the insulation adhesive in the thickness direction can be formed uniformly over the whole surface of the insulation sheet-like element. Because a diameter of the fiber determines a size of the flowing path, the insulation adhesive passes the flowing path and flows behind an upper surface of the fiber or an upper surface of the insulation sheet-like element, thereby enhancing the bonding between the circuit section and the heat radiation member.

Because the insulation sheet-like element is interposed between the circuit section and the heat radiation member, the circuit assembly can positively ensure a thickness of an insulation adhesive in comparison with an insulation layer formed by solidifying the adhesive in the prior art. Accordingly, it is possible to enhance reliability in insulation between the circuit section and the heat radiation member.

The best aspects embodying the invention will be described below by referring to the drawings.

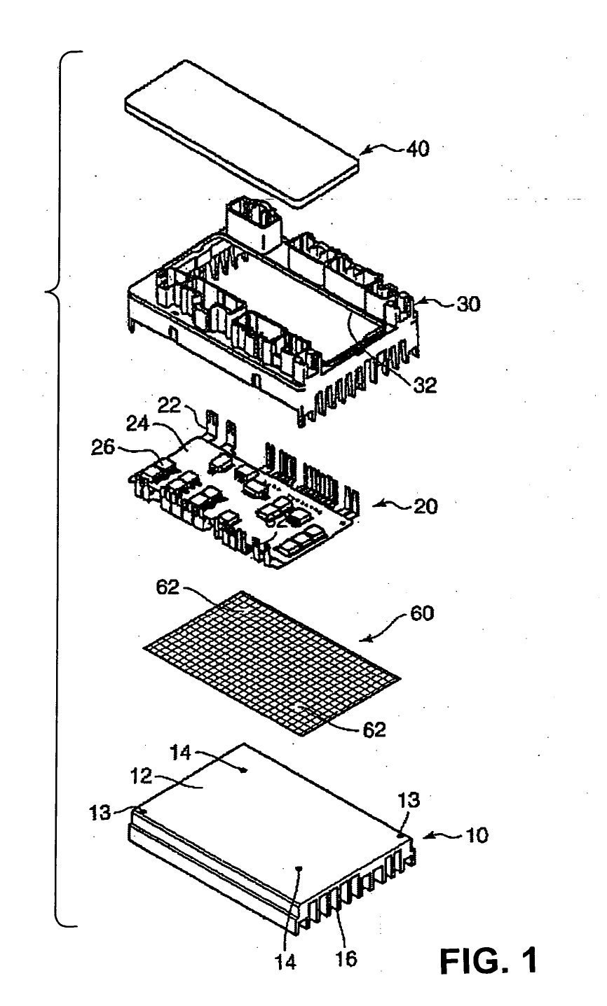

FIG. 1 is an exploded perspective view of a circuit assembly produced by a method in accordance with the invention. The circuit assembly includes a circuit section 20 constituting an electrical power circuit, a heat radiation member 10 having an bonding surface to which the circuit section 20 is adhered, a casing 30 surrounding the circuit section 20, and a cover 40 to be mounted on an opening 32 in the casing 30. An insulation sheet-like element 60 is disposed between the circuit section 20 and the heat radiation member 10.

The circuit section 20 includes a plurality of bus bars 22 constituting a distribution circuit and a control circuit substrate 24 for actuating semiconductor switching-devices 26 provided in the electrical power circuit. The bus bars 22 are adhered to the control circuit substrate 24. Electronic components, such as the semiconductor switching-devices 26 and resistance devices, are mounted on the circuit section 20.

The heat radiation member 10 is provided on the surface opposite from the bonding surface 12 with a plurality of fins 16. The bonding surface 12 is a rectangular shape and is provided in diagonal positions on an outer peripheral edge with holes 13 for recognition in image processing. The bonding surface 12 is also provided in inner positions on an outer peripheral edge with positioning holes 14 for positioning the sheet-like element 60 on the surface 12.

The insulation sheet-like element 60 is selected from a sheet-like material made by braiding insulation fibers, such as glass fibers. The sheet-like material made of braided insulation fibers has numerous clearances between the fibers. An insulation adhesive 50 described after is applied uniformly on the whole surface of the insulation sheet-like element 60 to flow into the clearances that define adhesive flow paths. The insulation sheet-like element 60 is provided with positioning holes 62 at the positions corresponding to the positioning holes 14 in the heat radiation member 10 when the element 60 is stacked on the bonding surface 12 of the heat radiation member 10.

The circuit section 20 is adhered to the heat radiation member 10 with the insulation sheet-like element 60 being disposed between the circuit section 20 and the bonding surface 12 of the heat radiation member 10. The casing 30 and cover 40 are mounted on the circuit section 20 to produce the circuit assembly.

Next, an exemplary method for adhering the circuit section 20 to the heat radiation member 10 while interposing the insulation sheet-like element 60 between the heat radiation member 10 and the circuit element 20 will be explained below.

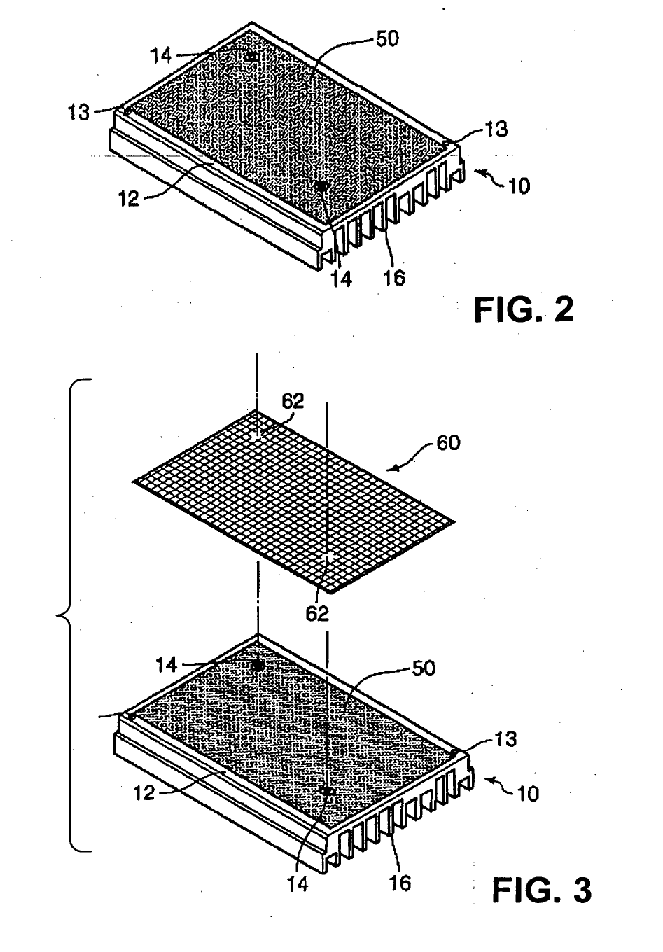

As shown in FIG. 2, the insulation adhesive 50 is applied to the bonding surface 12 of the heat radiation member 10. It should be noted that the insulation adhesive 50 is not applied to the positioning holes 14 for positioning the insulation sheet-like element 60 when applying the insulation adhesive 50 to the bonding surface 12. A screen-printing method will be preferable in applying the insulation adhesive because the method can easily distinguish an application area from a non-application area.

It will be possible to apply the insulation adhesive 50 to the holes 13 correctly by utilizing a screen-printing machine, which can automatically position a work and a screen so that the insulation sheet-like element 60 accords with the heat radiation member 10 while recognizing the holes 13 in the bonding surface 12 of the heat radiation member 10 by means of image processing.

Next, the insulation sheet-like element 60 is superposed on the insulation adhesive 50 before the insulation adhesive 50 is solidified. Because the insulation sheet-like element 60 is provided with the positioning holes 62 at the positions corresponding to the positioning holes 14 in the bonding surface 12 of the heat radiation member 10, as shown in FIG. 3, the insulation sheet-like element 60 can be superposed on the insulation adhesive 50 while recognizing visually to accord the positioning holes 62 in the insulation sheet-like element 60 with the positioning holes 14 in the heat radiation member 10.

The insulation sheet-like element 60 and heat radiation member 10 can be positioned by inserting a pin into each positioning hole 14 in the member 10 and receiving the pin in each positioning hole 62 in the insulation sheet-like element 60 as well as the visual positioning described above.

After superposing the insulation sheet-like element 60 on the insulation adhesive 50, the insulation adhesive 50 will seep through the numerous clearances or flow paths in the element 60 by a self-weight of the element 60 or a light pressure onto the element 60. In order to seep the insulation adhesive 50 through the flow paths in the insulation sheet-like element 60, it is preferable to set a thickness of the element 60 to be smaller than a thickness of the applied insulation adhesive 50 on the bonding surface 12. For example, if a thickness of the applied insulation adhesive 50 is 0.2 mm and a thickness of the insulation sheet-like element 60 is 0.1 mm, it is possible to seep the insulation adhesive 50 through the flow paths in the element 60 over the surface opposite from the circuit section 20.

The circuit section 20 will be closely disposed on the insulation adhesive 50 seeped through the insulation sheet-like element 60 by superposing the insulation sheet-like element 60 on the circuit section 20 and pressing the element 60 onto the bonding surface 12.

Finally, when the insulation adhesive 50 is solidified (for example, an epoxy base adhesive is solidified by heating), the circuit section 20 will be adhered to the heat radiation member 10 with the insulation sheet-like element 60 being interposed between them.

Even if a layer of the insulation adhesive 50 is collapsed by a relatively high pressure onto the circuit section 20 when the circuit section 20 is adhered to the heat radiation member 10, it is possible to ensure a minimum thickness of the insulation adhesive 50 through the insulation sheet-like element 60 interposed between the circuit section 20 and the bonding surface 12 by a work of applying the insulation adhesive 50 to the bonding surface 12 only at one time. Also, because the numerous flow paths that can pass the insulation adhesive 60 are formed in the insulation sheet-like element 60, the insulation adhesive 50 can be uniformly applied to the bonding surface of the circuit section 20 stacked on the insulation sheet-like element 60 and the positive bonding between the circuit section 20 and the heat radiation member 10 can be obtained through the insulation sheet-like element 60.

The insulation sheet-like element 60 is selected from a sheet-like material made by braiding the insulation fibers, so that the numerous flow paths that can pass the insulation adhesive 50 in the thickness direction can be formed uniformly over the whole surface of the insulation sheet-like element 60. As a diameter of the fiber determines a size of the flowing path, the insulation adhesive 50 passes the flowing path and flows behind an upper surface of the fiber or an upper surface of the insulation sheet-like element 60, thereby enhancing the bonding between the circuit section 20 and the heat radiation member 10.

Because the circuit assembly constructed above interposes the insulation sheet-like element 60 between the circuit section 20 and the heat radiation member 10, the circuit assembly can ensure a thickness of an insulation adhesive in comparison with an insulation layer formed by solidifying the insulation adhesive in the prior art. Accordingly, it is possible to enhance reliability in insulation between the circuit section 20 and the heat radiation member 10.

In the above embodiment, the insulation adhesive 50 seeps through the insulation sheet-like element 60 previously when the insulation sheet-like element 60 is stacked on the insulation adhesive 50 and the circuit section 20 is adhered to the heat radiation member 10 when the circuit section 20 is mounted on the insulation sheet-like element 60. However, the insulation adhesive 50 is not forcedly seeped through the insulation sheet-like element 60 when the element 60 is superposed on the insulation adhesive 50 and then the insulation adhesive 50 may seep through the insulation sheet-like element 60 by a pressure exerted when the circuit section 20 is pushed onto the insulation sheet-like element 60.

The insulation sheet-like element 60 is not limited to a sheet-like material made of the braided fibers. For example, a thin sheet made of an epoxy resin material can be used and pressed to provide numerous apertures as flow paths.

Because the insulation sheet-like element 60 and heat radiation member 10 can be positioned by guiding them along the their outer shapes when the element 60 is stacked on the heat radiation member 10, the positioning holes 14 and 62 formed in them in the above embodiment may be eliminated.

The insulation adhesive 50 is not necessarily applied to the bonding surface 12 of the heat radiation member 10 by screen-printing. The circuit assembly of the invention can be produced by a manually applying work of the insulation adhesive.

While the invention has been particularly described, in conjunction with specific preferred embodiments, it is evident that many alternatives, modifications, and variations will be apparent to those skilled in the art of the foregoing description. It is therefore contemplated that the appended claims will embrace any such alternatives, modifications, and variations as falling within the true scope and spirit of the invention.

1. A method for producing a circuit assembly by adhering a circuit section constituting an electrical power circuit to a bonding surface of a heat radiation member, comprising:
applying an insulation adhesive to the bonding surface of the heat radiation member;
superposing an insulation sheet-like element on the insulation adhesive before the insulation adhesive is solidified, the insulation sheet-like element having numerous flow paths through which the insulation adhesive can pass in a thickness direction of the element; and
superposing the circuit section on the insulation sheet-like element and pressing the circuit section toward the bonding surface, whereby the circuit section and heat radiation member are bonded to each other by the insulation adhesive seeping through the insulation sheet-like element.

2. The method for producing a circuit assembly according to claim 1, wherein an insulation sheet-like element having numerous flow paths is selected from a sheet-like material made by braiding insulation fibers in the element-superposing step.

3. A circuit assembly comprising:
a circuit section constituting an electrical power circuit;
a heat radiation member having a bonding surface to which the circuit section is adhered; and
an insulation sheet-like element having numerous flow paths through which the insulation adhesive passes in a thickness direction of the element, the insulation sheet-like element being interposed between the bonding surface of the heat radiation member and the circuit section, and the circuit section is adhered to the bonding surface.

4. The circuit assembly according to claim 3, wherein the insulation sheet-like element having numerous flow paths is selected from a sheet-like material made by braiding insulation fibers.
